(19) United States
(12) Patent Application Publication
(10) Pub. No.: US 2024/0133033 A1
(43) Pub. Date: Apr. 25, 2024

(54) REACTANT DELIVERY SYSTEM AND REACTOR SYSTEM INCLUDING SAME

(71) Applicant: ASM IP Holding B.V., Almere (NL)

(72) Inventors: Jacqueline Wrench, Mesa, AZ (US); Shuaidi Zhang, Chandler, AZ (US); Arjav Prafulkumar Vashi, Tempe, AZ (US); Shubham Garg, Gilbert, AZ (US); Todd Robert Dunn, Cave Creek, AZ (US); Moataz Bellah Mousa, Chandler, AZ (US); Jonathan Bakke, Phoenix, AZ (US); Ibrahim Mohamed, Mesa, AZ (US); Paul Ma, Scottsdale, AZ (US); Bo Wang, Chandler, AZ (US); Eric Shero, Phoenix, AZ (US); Jereld Lee Winkler, Gilbert, AZ (US)

(21) Appl. No.: 18/403,024

(22) Filed: Jan. 3, 2024

Related U.S. Application Data
(63) Continuation-in-part of application No. 18/074,629, filed on Dec. 5, 2022.
(60) Provisional application No. 63/265,139, filed on Dec. 8, 2021.

(51) Int. Cl. C23C 16/455; C23C 16/52

(52) U.S. Cl. CPC C23C 16/45561; C23C 16/52

(57) ABSTRACT

Herein disclosed are systems and methods related to delivery systems using solid source chemical fill vessels. The delivery system can include a vapor deposition reactor, two or more fill vessels, of which one of more can be remote from the vapor deposition reactor. Each fill vessel is configured to hold solid source chemical reactant therein. An interconnect line or conduit can fluidly connect the vapor deposition reactor with one or more of the fill vessels. A line heater can heat at least a portion of the interconnect line to at least a minimum line temperature.

### CROSS-REFERENCE TO RELATED APPLICATIONS

This application is a continuation-in-part application, which claims priority to U.S. Ser. No. 18/074,629, filed Dec. 5, 2022, and entitled “REMOTE SOLID SOURCE REACTANT DELIVERY SYSTEMS FOR VAPOR DEPOSITION REACTORS,” which is a non-provisional of and claims priority to and the benefit of U.S. Provisional Patent Application No. 63/265,139, filed Dec. 8, 2021, and entitled “REMOTE SOLID SOURCE REACTANT DELIVERY SYSTEMS FOR VAPOR DEPOSITION REACTORS,” which are hereby incorporated herein by reference in their entirety.

### FIELD

The present application relates generally to systems and methods including or involving semiconductor processing equipment, and more specifically to solid source reactant delivery systems for vapor deposition reactors.

### BACKGROUND

Solid source reactant delivery systems can be used to deliver reactant vapor to a vapor deposition reactor, including a vapor deposition reaction chamber. The solid source reactant delivery system can include a vessel, which can contain a solid source reactant that is to be vaporized. During operation of the vapor deposition reactor, the solid source reactant can be vaporized and carried by a carrier gas or drawn as vapor alone to the reaction chamber, where the reactant can take part in a chemical reaction to deposit material on a substrate. As the reactant is vaporized, it may be depleted and require refilling or replenishing. However, there currently exists certain limitations on how quickly and effectively the solid source reactant can be replenished while reducing downtime of the vapor deposition reactor. Accordingly, improved reactant delivery systems, reactor systems including the reactant delivery systems, and methods of using the same are desired.

Any discussion of problems and solutions set forth in this section has been included in this disclosure solely for the purpose of providing a context for the present disclosure and should not be taken as an admission that any or all of the discussion was known at the time the invention was made.

### SUMMARY

Solid source reactant delivery systems and methods for a vapor deposition reactor are disclosed. In some embodiments, a solid source reactant delivery system includes a first bulk fill vessel that is remote from the vapor deposition reactor. The first bulk fill vessel can be configured to hold a first solid source chemical reactant therein. The first bulk fill vessel can include a first fluid outlet that is configured to pass a first vaporized chemical reactant out of the first vessel body. The delivery system can further include a second bulk fill vessel that is remote from the vapor deposition reactor and that is configured to hold a second solid source chemical reactant therein. The second bulk fill vessel can include a second fluid outlet that is configured to pass a second vaporized chemical reactant out of the second vessel body. The delivery system can include an interconnect line that fluidly connects the vapor deposition reactor with each of the first and second bulk fill vessels. The vapor deposition reactor can be separated from both of the first and second bulk fill vessels by at least a minimum distance. The delivery system can further include a line heater that is configured to heat at least a portion of the interconnect line to at least a minimum line temperature. The delivery system can include a gas panel that includes a valve. The gas panel can be disposed between the interconnect line and each of the first and second bulk fill vessels. The valve can be configured to selectively flow the first vaporized chemical reactant from the first fluid outlet and the second vaporized chemical reactant from the second fluid outlet through the interconnect line.

In accordance with additional embodiments of the disclosure, an exemplary reactant delivery system includes a first vessel, a first housing enclosing the first vessel, a second vessel, a conduit fluidly coupled to the second vessel and the first vessel, and a flow control device within the conduit to control an amount of transfer of a vapor of a solid source reactant from the second vessel to the first vessel. In accordance with examples of these embodiments, the first vessel includes a first vessel inlet and a first vessel outlet. The first vessel can form part of a reactor system and can be configured to retain the solid source reactant. In accordance with further examples, the second vessel is exterior the first housing. The second vessel can be configured to retain the solid source reactant. The second vessel can be remote from the reactor system. In accordance with further examples, a pressure within the first housing is less than an ambient pressure exterior the first housing. In accordance with yet further examples, the reactant delivery system further includes a valve plate within the first housing. The valve plate can include one or more valves fluidly coupled to the first vessel outlet. In accordance with further examples, the reactant delivery system includes a pressure transducer to measure a pressure within the conduit. In accordance with yet further examples, the reactant delivery system includes a second housing enclosing the second vessel. In such cases, a pressure within the second housing can be greater than a pressure within the first housing. Exemplary reactant delivery systems also include a controller. The controller can be configured to control a temperature of the first vessel and a temperature of the second vessel. For example, the controller can be configured to regulate a temperature of a bottom portion of the first vessel to be lower than a temperature of a top portion of the first vessel. Additionally or alternatively, the controller can be configured to automatically heat the second vessel, when an amount of reactant in the first vessel is below a threshold amount.

In accordance with yet further embodiments of the disclosure, a reactant delivery system includes a first vessel, a second vessel, a third vessel, a conduit, and a flow control device. In accordance with examples of the disclosure, the first vessel includes a first vessel inlet and a first vessel outlet. The first vessel can form part of a reactor system and be configured to retain a solid source reactant. The second vessel and the third vessel are also configured to retain the solid source reactant. The flow control device can be configured to control an amount of transfer of a vapor of the solid source reactant from the third vessel to one or more of the first vessel or the second vessel. The first vessel outlet and/or a second vessel outlet can be fluidly coupled to one or more reaction chambers (e.g., inlets to the reaction chambers).

In accordance with yet further examples, a reactor system includes one or more process modules and a reactant delivery system, such as a reactant delivery system described herein. By way of example, the reactant delivery system can include a first vessel, a second vessel, a third vessel, a conduit, and a flow control device. The first vessel can include a first vessel inlet and a first vessel outlet, the first vessel forming part of a reactor system and configured to retain a solid source reactant. The second vessel can include a second vessel outlet. The second vessel can be configured to retain the solid source reactant. The third vessel can include a third vessel outlet, the third vessel can be remote from the reactor system and configured to retain the solid source reactant. The conduit can fluidly couple the third vessel outlet to the first vessel inlet and/or to the second vessel inlet. The flow control device can be disposed within the conduit to control an amount of transfer of a vapor of the solid source reactant from the third vessel to one or more of the first vessel or the second vessel. The second vessel outlet can be fluidly coupled to one or more (e.g., each) of the process modules.

This summary is provided by way of example only and should not be viewed as limiting this disclosure in any way. Other embodiments are described below in conjunction with the associated drawings.

### BRIEF DESCRIPTION OF THE DRAWINGS

These and other aspects of the disclosure will be readily apparent to the skilled artisan in view of the description herein, the appended claims, and from the drawings, which are intended to illustrate and not to limit the invention, and wherein:

FIG. 1 schematically shows an example remote solid source reactant delivery system, according to some configurations.

FIG. 2 schematically shows another example remote solid source reactant delivery system, according to some configurations.

FIG. 3 shows an example method for delivering vaporized chemical reactant to a vapor deposition reactor, according to some configurations.

FIG. 4 schematically illustrates a reactant delivery system in accordance with additional examples of the disclosure.

FIG. 5 schematically illustrates a reactant delivery system in accordance with yet additional examples of the disclosure.

FIG. 6 illustrates a reactor system in accordance with yet additional examples of the disclosure.

It will be appreciated that elements in the figures are illustrated for simplicity and clarity and have not necessarily been drawn to scale. For example, the dimensions of some of the elements in the figures may be exaggerated relative to other elements to help improve understanding of illustrated embodiments of the present disclosure.

### DETAILED DESCRIPTION

The headings provided herein, if any, are for convenience only and do not necessarily affect the scope or meaning of the claimed invention. Described herein are systems and related methodologies for delivering vapor phase reactant from a solid source reactant. Such systems and methodologies are suitable for use with, for example, high capacity deposition modules.

The following detailed description describes certain specific embodiments to assist in understanding the claims. However, one may practice the present invention in a multitude of different embodiments and methods, as defined and covered by the claims.

Reaction processes can include a variety of processes, including vapor deposition processes, such as Chemical Vapor Deposition (CVD) and Atomic Layer Deposition (ALD), vapor etch processes, and other processes in the semiconductor industry for forming and patterning thin films of materials on substrates, such as silicon wafers. In vapor deposition processes, reactant vapors (including “precursor gases”) of different reactant chemicals are delivered to one or more substrates in a reaction chamber. In some cases, the reaction chamber includes only a single substrate supported on a substrate holder (such as a susceptor), with the substrate and substrate holder being maintained at a desired process temperature. In other cases the reaction chamber may hold two, three or more substrates to be processed.

In typical CVD processes, one or more reactive reactant vapors react with one another and/or a substrate surface to form thin films on the substrate, with the growth rate generally being related to the temperature and the amounts of reactant gases. In some variants, energy to drive the deposition reactants is supplied in whole or in part by plasma. Production of electronic devices, such as semiconductor devices, may include multiple reactant steps in which a vapor phase reactant is provided to a reaction chamber, such as one or more steps in which a precursor is provided in a vapor deposition process and/or one or more etch steps.

During a reactant provision step, a gaseous (e.g., vaporized) reactant is delivered into a vapor deposition reaction chamber of a vapor deposition reactor. The reactant may be a solid source that is vaporized in a sublimator, such as a solid source sublimator, prior to being conducted into the reaction chamber. The sublimator can heat the solid source chemical reactant (sometimes referred to herein as solid source reactant or simply reactant) to above a minimum sublimation temperature that is configured to vaporize the solid source reactant. The minimum sublimation temperature may be generally dependent on a type of solid source reactant.

Another known process for forming thin films on substrates is ALD. In many applications, ALD uses a liquid and/or solid source chemical as described herein. ALD is a type of vapor deposition wherein a film is built up through generally self-saturating reactions performed in cycles. A thickness of the film is generally determined by the number of cycles performed. In an ALD process, gaseous reactants are supplied, alternatingly and/or repeatedly, to the substrate or wafer to form a thin film of material on the wafer. One reactant adsorbs in a self-limiting process on the wafer. A different, subsequently pulsed reactant reacts with the adsorbed material to form a single molecular layer of the desired material. Decomposition may occur through mutual reaction between the adsorbed species and with an appropriately selected reagent, such as in a ligand exchange or a gettering reaction. In some ALD reactions, no more than a molecular monolayer forms per cycle. Thicker films are produced through repeated growth cycles until the target thickness is achieved.

In some ALD reactions, mutually reactive reactants are kept separate in the vapor phase with intervening removal processes between substrate exposures to different reactants. For example, in time-divided ALD processes, reactants are provided in pulses to a stationary substrate, typically separated by purging and/or pump down phases; in space-divided ALD processes, a substrate is moved through zones with different reactants; and in some processes, aspects of both space-divided and time-divided ALD can be combined. The skilled artisan will appreciate that some variants or hybrid processes allow some amount of CVD-like reactions, either through selection of the deposition conditions outside the normal ALD parameter windows and/or through allowing some amount of overlap between mutually reactive reactants during exposure to the substrate.

Delivery of the vaporized solid source reactant from the sublimator to the vapor deposition reaction chamber can be controlled by the delivery mechanism that delivers the reactant vapor. In some embodiments, the sublimator may be disposed within the vapor deposition reactor, such as near one or more vapor deposition reaction chambers. This can provide more immediate delivery of the reactant vapors to the reaction chamber. However, this arrangement can require a significant down time for the reactor while the sublimator is refilled with solid source reactant.

To address this issue, in some embodiments, the sublimator can be disposed remote from the vapor deposition reactor. This remoteness or separateness can provide greater flexibility with regard to space and therefore may reduce space constraints. Moreover, using a remote delivery system as described herein can allow for refilling the sublimator without having to interrupt semiconductor processing or with significantly reduced interruption. Instead, in accordance with examples of the disclosure, the sublimator can be refilled during operation of the reactor, and this refilling may not significantly affect processing of the substrates. Thus, remote delivery systems can improve throughput of the semiconductor processing.

A sublimator can generally refer to any container or vessel that vaporizes reactant, such as solid source reactant. A sublimator may include a housing or body that contains the solid source reactant. A sublimator can include one or more bulk fill vessels. For example, a remote sublimator may include a plurality of bulk fill vessels disposed within a housing. Other arrangements are possible.

A solid source reactant delivery system can include one or more of a solid and/or liquid fill vessel (or source vessel) and a heater (e.g., a radiant heat lamp, resistive heater, and/or the like). For example, the fill vessel can be heated in a vacuum enclosure, for example, with resistive cable and/or rod heaters. The fill vessel can include the chemical reactant (which may also be referred to as “chemical precursor” or “source precursor”), which can be a solid (e.g., in powder form) or liquid. The heater heats up the vessel to facilitate the vaporization and/or sublimation of the reactant in the vessel.

The vessel can have an inlet and an outlet for the flow of a carrier gas, such as an inert gas (e.g., N₂, Ar, He, etc.) through the vessel. Generally, the carrier gas conveys reactant vapor (e.g., evaporated or sublimated chemical reactant) along with it through the vessel outlet and ultimately to a reaction chamber. The vessel typically includes isolation valves for fluidly isolating the contents of the vessel from the vessel exterior. The isolation valves may be disposed on or near a lid of the fill vessel.

The fill vessel of some embodiments comprises, consists essentially of, or consists of a sublimator. As such, wherever a “source vessel” or “fill vessel” or simply “vessel” is mentioned herein, a sublimator (such as a “solid source chemical sublimator”) is also expressly contemplated.

In some applications, the reactant gases are stored in gaseous form in a reactant fill vessel. In such applications, the reactants are often gaseous at standard pressures and temperatures of around 1 atmosphere and room temperature. Examples of such gases include nitrogen, oxygen, hydrogen, and ammonia. However, in some cases, the vapors of the chemical reactant (“precursors”) that are solid (e.g., hafnium chloride, hafnium oxide, zirconium dioxide, and the like) at standard pressure and temperature are used. For some chemical reactants, the vapor pressure at room temperature is so low that they are typically heated and/or maintained at very low pressures to produce a sufficient amount of reactant vapor for the reaction process. Once vaporized (e.g., sublimed or evaporated), keeping the vapor phase reactant at or above the vaporizing temperature through the processing system can prevent undesirable condensation in the valves, filters, conduits, and other components associated with delivering the vapor phase reactants to the reaction chamber. Vapor phase reactants from such naturally solid or liquid substances are useful for chemical reactions in a variety of other industries.

Reactant fill vessels are supplied with gas lines extending from the inlet and outlet, isolation valves on the lines, and fittings on the valves, the fittings being configured to connect the gas flow lines to the reactor. For example, an interconnect line may connect the sublimator and/or some other portion of the delivery system with the reactor. It is often desirable to provide a number of additional heaters for heating the various valves and gas flow lines between the reactant fill vessel or sublimator and the reactor, to prevent the reactant vapor from condensing and depositing on such components. Accordingly, the gas-conveying components between the fill vessel and the reaction chamber are sometimes referred to as a “hot zone” in which the temperature is maintained above the vaporization/condensation/sublimation temperature of the reactant. The temperatures needed to vaporize the reactant may be different from temperatures needed to avoid condensation within the lines, valves, etc. Accordingly, acceptable temperature ranges may be different within the sublimator than within a gas line (e.g., interconnect line) or within another element, as described in more detail below.

A remote fill vessel may deliver vaporized reactant to a reaction chamber directly. However, in some embodiments, the remote fill vessel may be configured to fill a reactant fill vessel within the reactor or elsewhere with a chemical reactant as described herein. The vessel may include an “intermediate fill” vessel, a “transfill” vessel, or a “bulk” vessel or similar (for conciseness, the intermediate fill vessel or transfill vessel may be referred to herein simply as a “fill vessel”). Examples of some transfill vessels are disclosed in U.S. Patent Application Publication No. 2021/0071301, filed on Sep. 3, 2020, titled “FILL VESSELS AND CONNECTORS FOR CHEMICAL SUBLIMATORS,” which is hereby incorporated by reference herein in its entirety for all purposes.

When the chemical reactant is depleted and in need of replacement, it is customary to replace the entire fill vessel with a new one that has a full load of the chemical reactant. Replacing the fill vessel requires shutting off associated valves, disconnecting and physically removing the fill vessel, placing a new fill vessel in the appropriate location, and connecting fittings of the new fill vessel to the remaining substrate processing apparatus. Often, this process also involves disassembling various thermocouples, line heaters, clamps, and the like. These processes can be somewhat laborious and time consuming.

Delivery systems described herein having fill vessels can advantageously reduce a need to replace or refill a sublimator within a reactor. Instead, the fill vessel can be used to automatically and/or continuously supply the reactor system with a chemical reactant. The flow may additionally or alternatively be pulsed. A fill chamber system can include one or more fill vessels. Furthermore, fill vessels in accordance with embodiments herein can be disposed near, adjacent, or within a reactor. As noted above, since the fill vessel does not need to be removed from a reactor system for refilling, the fill vessel can achieve advantages of disposition proximal to or within reactor systems (such as relatively short flow paths), without the labor and downtime associated with refilling. Additional features are described herein with reference to various configurations.

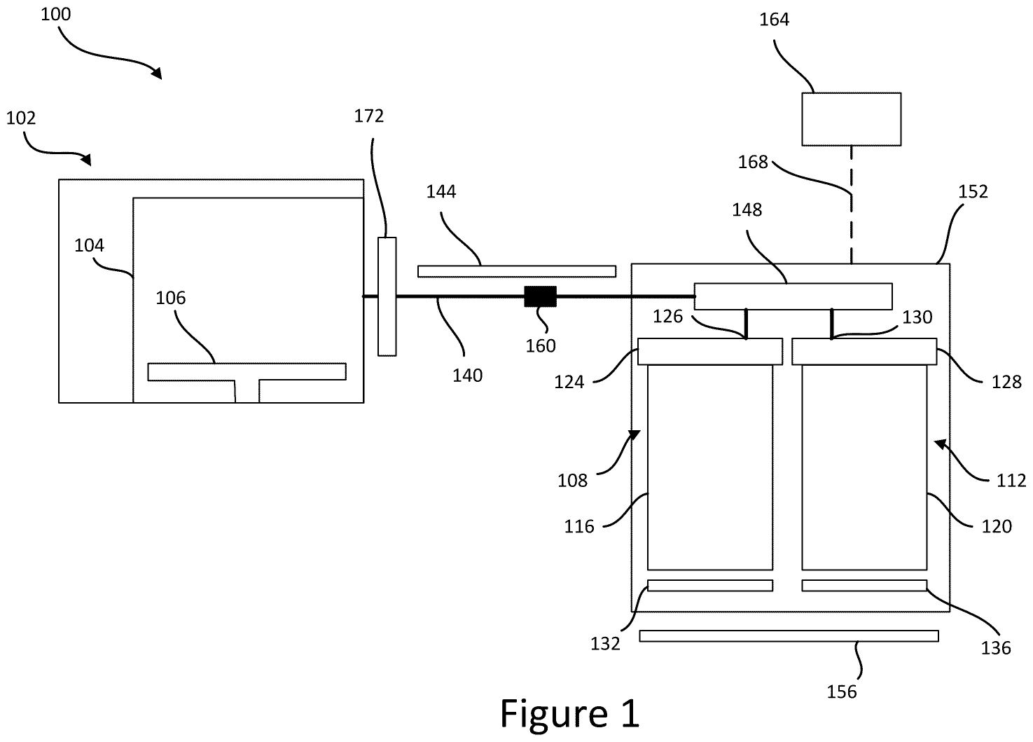

FIG. 1 schematically shows an example remote solid source reactant delivery system 100, according to some configurations. The remote solid source reactant delivery system 100 can include a vapor deposition reactor 102, a plurality of bulk fill vessels 108, 112, and an interconnect line 140 that fluidly connects the plurality of bulk fill vessels 108, 112 with the vapor deposition reactor 102.

The vapor deposition reactor 102 can include one or more vapor deposition reaction chambers 104. Each vapor deposition reaction chamber 104 can include one or more substrate supports 106. The substrate support 106 can be configured to receive a substrate therein and allow reactant gas to pass thereover, as described above.

Each of the bulk fill vessels 108, 112 can include corresponding vessel bodies 116, 120, vessel lids 124, 128, and fluid outlets 126, 130 configured to pass vaporized chemical reactant out of the corresponding vessel bodies 116, 120 and toward the interconnect line 140. The bulk fill vessels 108, 112 can each be configured to hold solid source chemical therein. In some embodiments, the first bulk fill vessel 108 may be configured to hold the same chemical reactant as the second bulk fill vessel 112. However, each may hold different chemical reactant in some embodiments.

Generally, each of the bulk fill vessels 108, 112 contains solid chemical reactant, but liquid chemical reactant is possible. The terms “solid source precursor” and “solid source chemical reactant” may be generally used interchangeably and have their customary and ordinary meaning in the art in view of this disclosure. These terms refer to a source chemical that is solid under standard conditions (i.e., room temperature and atmospheric pressure).

Each of the vessel lids 124, 128 is adapted to be mechanically attached to a top of the corresponding vessel bodies 116, 120. This may be done using one or more of attachment devices (e.g., bolts, screws, etc.). In certain embodiments, the vessel lids 124, 128 and vessel bodies 116, 120 are mechanically attached in a gas-tight fashion. The vessel bodies 116, 120 can be shaped to reduce a footprint and to hold a significant amount of chemical reactant therein (see below).

Each of the bulk fill vessels 108, 112 can include corresponding vessel heaters 132, 136 that are configured to heat the corresponding bulk fill vessels 108, 112. The first vessel heater 132 and the second vessel heater 136 can be operated independently from one another. This can allow operation of one of the vessel heaters 132, 136 while the other one is temporarily turned off and/or while the other corresponding bulk fill vessel 108, 112 is replaced or refilled. The vessel heaters 132, 136 can be disposed below the corresponding bulk fill vessels 108, 112, as shown in FIG. 1. However, other configurations are possible. For example, the vessel heaters 132, 136 can be disposed within the corresponding vessel bodies 116, 120. The heater can include a heating pad, heating rod, heating jacket, heating blade, heating lamp, or other heater.

One or more of the bulk fill vessels 108, 112 can be at least partially housed within a housing 152. The housing 152 can include a metal housing. The housing 152 may be insulated to prevent or reduce the flow of heat out of the housing. This may reduce the likelihood of condensate developing within one or more lines or valves of the remote solid source reactant delivery system 100. The housing 152 can serve as a central repository for holding chemical reactant and an intuitive central point for accessing and refilling the chemical reactant.

An interior of the housing or cabinet 152 can be kept at a reduced pressure (e.g., 1 mTorr to 10 Torr, and often about 500 mTorr). This reduced pressure can promote radiant heating of the bulk fill vessels 108, 112 within the housing 152 and/or to thermally isolate the vessels from each other to facilitate more uniform temperature fields. In other variations, the housing 152 is not evacuated and includes convection-enhancing devices (e.g., fans, cross-flows, etc.). Reflector sheets can be provided, which may be configured to surround the components within the housing 152 to reflect the radiant heat generated by the heating devices 132, 156 to the components positioned within the housing 152. Reflector sheets can be provided on the inner walls of the housing 152, as well as on the housing ceiling and floor.

The remote solid source reactant delivery system 100 can include a gas panel 148 that includes one or more valves for controlling a flow of vapor therethrough and/or between the bulk fill vessels 108, 112 and the vapor deposition reactor 102. The gas panel 148 may be disposed between the interconnect line 140 and each of the bulk fill vessels 108, 112. Additionally or alternatively, the vapor deposition reactor 102 can include a reactor gas panel 172 that includes one or more corresponding valves configured to control a flow of gas into the vapor deposition reaction chamber 104. The reactor gas panel 172 can direct a flow of vaporized reactant to one or more vapor deposition reaction chambers of the vapor deposition reactor 102.

Flow from the bulk fill vessels 108, 112 to the vapor deposition reactor 102 via the interconnect line 140 may not be simultaneous from each of the bulk fill vessels 108, 112, but may instead be switchable such that flow to the vapor deposition reactor 102 can be switched from the first bulk fill vessel 108, exclusively, to the second bulk fill vessel 112, exclusively, and vice versa. Each of the one or more valves of the gas panel 148 can be configured to switch a flow of vaporized chemical reactant through the interconnect line 140 from exiting the first fluid outlet 126 to exiting the second fluid outlet 130. The switchability may allow the vapor deposition reactor 102 to receive uninterrupted flow of reactant. Accordingly, when the first bulk fill vessel 108 is to be refilled with chemical reactant, the gas panel 148 (e.g., via the one or more valves) can seamlessly switch the flow to come from the second bulk fill vessel 112. This seamless transition may be referred to as a “hot swap” of gas flow.

The vaporized reactant is generally maintained above a threshold temperature to avoid condensation of the reactant within a vessel, valve, line, etc. Accordingly, lines feeding vaporized reactant to the vapor deposition reactor 102 are generally heated. To perform the hot swap mentioned above, each of the bulk fill vessels 108, 112 may be heated to at least a minimum vessel temperature in order to vaporize the chemical reactant. In some embodiments, the temperatures within each of the bulk fill vessels 108, 112 is approximately the same. The minimum vessel temperature may be dependent on the chemical that is held within the corresponding bulk fill vessel 108, 112 and the associated pressure. Additionally or alternatively, the minimum vessel temperature may be at least partially dependent on a flow rate of vapor out of the bulk fill vessels 108, 112. For example, the minimum vessel temperature may be about 85° C., about 90° C., about 95° C., about 100° C., about 105° C., about 110° C., about 115° C., about 120° C., about 125° C., about 130° C., about 135° C., about 140° C., about 145° C., about 150° C., about 155° C., about 160° C., about 165° C., about 170° C., about 175° C., about 180° C., any value therebetween, or fall within any range having endpoints therein. For example, the minimum vessel temperature may be between about 105° C. and about 155° C., and in some examples is about 135° C. at vapor pressure of about 150 Torr and a flow rate of about 100 sccm. Other temperatures and pressures can be achieved with the hardware designs disclosed herein. A vessel temperature of between about 135° C. and about 150° C. appears to be an effective range that generally maintains the vaporized chemical reactant at standard pressures and flow rates without expending excess energy.

The interconnect line 140 may be heated by a line heater 144 of the remote solid source reactant delivery system 100. The line heater 144 can be any kind of heater known in the art, such as a heating jacket that at least partially surrounds the interconnect line 140. The line heater 144 may be configured to heat at least a portion of the interconnect line 140 to at least a minimum line temperature. The line heater 144 may be configured to insulate the portion of the interconnect line 140 from temperature variations once a temperature above a minimum line temperature has been achieved. The minimum line temperature may be generally higher than the minimum vessel temperature, and may be dependent on the chemical that is held within the corresponding bulk fill vessel 108, 112, the associated pressure within the interconnect line 140, and/or on a flow rate of vapor out of the bulk fill vessels 108, 112. For example, the minimum line temperature may be about 115° C., about 120° C., about 125° C., about 130° C., about 135° C., about 140° C., about 145° C., about 150° C., about 155° C., about 160° C., about 165° C., about 170° C., about 175° C., about 180° C., about 185° C., about 190° C., about 195° C., about 200° C., about 205° C., about 210° C., about 215° C., any value therebetween, or fall within any range having endpoints therein. For example, the minimum line temperature may be between about 140° C. and about 190° C., and in some examples is about 155° C. at vapor pressure of about 120 Torr and a flow rate of 100 sccm. A line temperature of between about 140° C. and about 190° C. appears to be an effective range that generally maintains the vaporized chemical reactant at standard pressures and flow rates without expending excess energy.

In some embodiments, the housing 152 includes a housing heater 156. The housing heater 156 may be disposed near, adjacent to, and/or within the housing 152. The housing heater 156 may be configured to heat the housing 152 to at least a minimum housing temperature. The minimum housing temperature may be below the minimum vessel temperature and/or the minimum line temperature.

In some embodiments, the remote solid source reactant delivery system 100 includes a flow controller 160 or flow meter that is configured to modify a flux of vaporized chemical reactant through the interconnect line 140. The flow controller 160 can be in fluid communication with the interconnect line 140, and/or the flow controller 160 may monitor a flow of vapor through the interconnect line 140. The flow controller 160 can measure a flow rate of the vapor. The monitoring may be updated repeatedly (e.g., regularly), such as over a regular interval. The flow controller 160 may be coupled to a flow control valve (e.g., needle valve, metering valve, etc.) that can control the flux of vaporized chemical reactant through the interconnect line 140. The flow controller 160 may receive a signal (e.g., from a flow control sensor within the interconnect line 140) that the amount of flux through the interconnect line 160 is too high or too low. The flow controller 160 can then send a signal to the flow control valve to decrease or increase the flux of vapor through the interconnect line 160.

The remote solid source reactant delivery system 100 can include a vessel controller 164 that is configured to track an amount of chemical reactant within the bulk fill vessels 108, 112. The vessel controller 164 can include one or more sensors configured to identify the amount of reactant in each of the bulk fill vessels 108, 112. Additionally or alternatively, the vessel controller 164 may be configured to receive an indication when one or more of the bulk fill vessels 108, 112 holds an amount of chemical outside of a threshold amount of reactant. For example, the vessel controller 164 may obtain a signal from the one or more sensors indicating that a volume of solid source chemical reactant within the first bulk fill vessel 108 is below a minimum threshold amount. In response to the signal, the vessel controller 164 may instruct one or more valves of the gas panel 148 to switch the flow of vaporized chemical reactant through the interconnect line from being from the first fluid outlet to being from the second fluid outlet.

In some embodiments, the vessel controller 164 can transmit a notification to a user interface that the amount of chemical in the one or more of the bulk fill vessels 108, 112 is outside the threshold amount. The threshold amount may be a maximum threshold (e.g., a signal is generated when the amount goes above the maximum threshold) or a minimum threshold (e.g., a signal is generated when the amount goes below the minimum threshold). The vessel controller 164 may communicate with the housing 152 and/or any element therein via the vessel controller connection 168. The vessel controller connection 168 may be a wired or wireless connection.

The housing 152 and/or one or more of the bulk fill vessels 108, 112 may be disposed remote from the vapor deposition reactor 102. The capability of remoteness can provide additional flexibility in where to place the bulk fill vessels 108, 112. Additionally or alternatively, this can allow at least one of the bulk fill vessels 108, 112 to have sufficient chemical reactant therein in order to reduce an amount of time needed to refill the amount of the chemical reactant within the housing 152 for delivery to the vapor deposition reactor 102. In some embodiments, the interconnect line 140 separates the vapor deposition reactor 102 from the housing 152 and/or the bulk fill vessels 108, 112 by a minimum distance. The minimum distance may be determined in part by the chemical reactant, flow rate, and/or pressure within the interconnect line 140. The minimum distance may be about 3 m, about 5 m, about 8 m, about 10 m, about 15 m, about 18 m, about 20 m, about 25 m, about 30 m, about 35 m, about 40 m, any value therebetween, or fall within any range having endpoints therein. For example, in some embodiments the minimum distance is about 15 m. A total separation distance in some embodiments is about 30 m.

The ratio of the height of each of the bulk fill vessels 108, 112 to the width/diameter thereof can be such that a footprint of the remote solid source reactant delivery system 100 is reduced. The ratio of a height to a width can be greater than about 1, greater than about 1.5, greater than about 2, greater than about 3, greater than about 4, greater than about 5, greater than about 6, greater than any value therebetween, or fall within any range having endpoints therein. For example, in some embodiments, the ratio of height to width is about 1.54. In some embodiments, a height of the bulk fill vessels 108, 112 is about 85 cm and a width is about 55 cm. Each of the bulk fill vessels 108, 112 can be configured to hold a significant amount of solid source chemical reactant. This ability to hold so much chemical reactant can reduce a need to refill each bulk fill vessel, thus reducing a chance for errors in refilling and to reduce human intervention. Each of the bulk fill vessels 108, 112 can be configured to hold about 16 L of chemical reactant therein. Based on the chemical, each of the bulk fill vessels 108, 112 can hold at least 18 kg of chemical reactant. It may be advantageous to minimize the volume or footprint that the bulk fill vessels 108, 112 would entail, for example, so that it may be placed in more locations as necessary. Compact vessel assemblies can reduce such a footprint. In certain embodiments, each of the bulk fill vessels 108, 112 can have an area (e.g., on which the corresponding bulk fill vessel 108, 112 is placed) of between about 2000 cm² and about 3500 cm².

Each of the vessel lids 124, 128 may include corresponding carrier gas inlets (not shown) that can allow flow of a carrier gas therethrough. The carrier gas inlets can include a corresponding valve, which may be included in the gas panel 148. The carrier gas can couple with sublimed or evaporated chemical within the bulk fill vessels 108, 112. The effluent from the bulk fill vessels 108, 112 then includes the carrier gas and the reactant gas vaporized from within an interior of the bulk fill vessels 108, 112. In some embodiments, the interior of the bulk fill vessels 108, 112 is configured to contain a headspace after it is filled with chemical reactant. The headspace can be in fluid communication with the corresponding carrier gas inlets and/or fluid outlets 126, 130, and can be configured for sublimation of the chemical reactant by the fluid (e.g., carrier gas) in the headspace.

As noted above, inactive or inert gas is preferably used as the carrier gas for the vaporized chemical reactant. The inert gas (e.g., nitrogen, argon, helium, or the like) may be fed into the bulk fill vessels 108, 112 through the corresponding carrier gas inlet. It will be appreciated that additional valves and/or other fluidic control elements may be included that are not shown.

The effluent (e.g., carrier gas plus evaporated chemical) can pass through the fluid outlets 126, 130, through the gas panel 148 and the interconnect line 140, and to the vapor deposition reactor 102. In some embodiments, each of the fluid outlets 126, 130 comprises a corresponding filter (not shown in FIG. 1) that is configured to prevent a passage of particulate matter therethrough. The filter can help ensure that no particulate matter is passed into the vapor deposition reactor 102 (e.g., into the vapor deposition reaction chamber 104). In some embodiments, the interconnect line 140 connects directly to the vapor deposition reaction chamber 104. Additional information about example solid source chemical sublimators and/or fluidics thereof may be found in U.S. Pat. No. 8,137,462, issued on Mar. 20, 2012, and titled “PRECURSOR DELIVERY SYSTEM,” which is hereby incorporated by reference herein in its entirety for all purposes. It will be appreciated that additional valves and/or other fluidic elements may be included that are not shown. The bulk fill vessels 108, 112 can have additional or alternative features disclosed, for example, in U.S. Pat. No. 10,876,205, filed on Sep. 30, 2016, and titled “REACTANT VAPORIZER AND RELATED SYSTEMS AND METHODS,” which is hereby incorporated by reference herein in its entirety for all purposes.

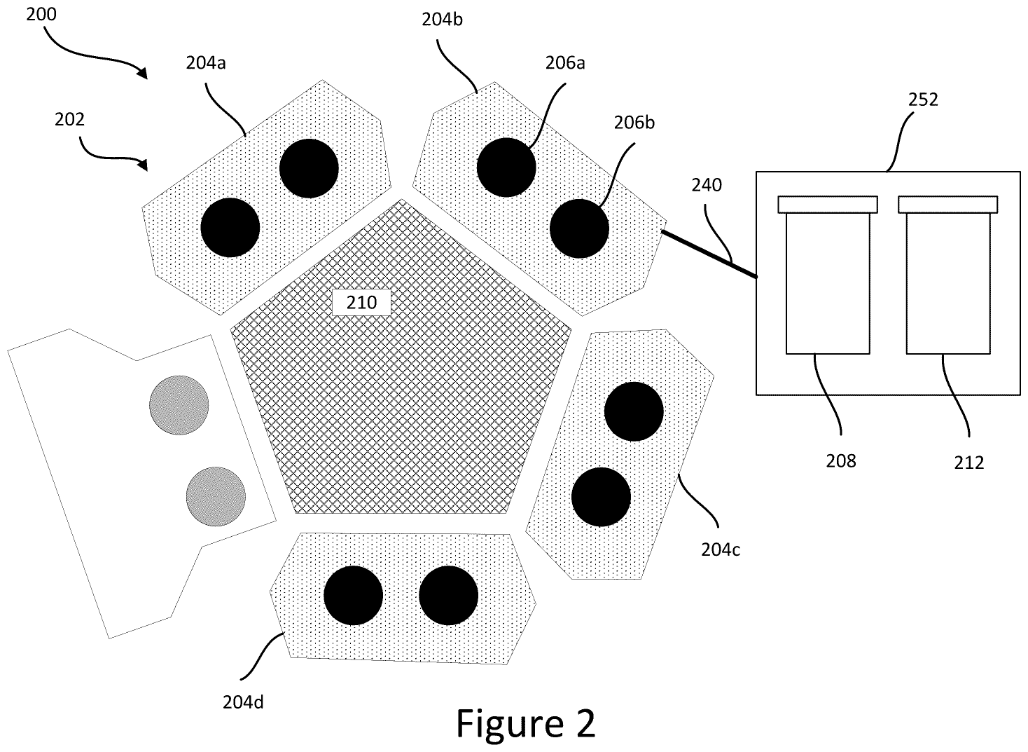

FIG. 2 schematically shows another example remote solid source reactant delivery system 200, according to one embodiment. The remote solid source reactant delivery system 200 can include a plurality of bulk fill vessels 208, 212 within a housing 252, and a vapor deposition reactor 202. The vapor deposition reactor 202 can include a substrate handling chamber 210 and one or more housing modules 204a, 204b, 204c, 204d. As shown, the interconnect line 240 can directly connect the housing 252 (or any element(s) therein) and the one or more housing modules 204a, 204b, 204c, 204d. In some embodiments, the interconnect line 240 may indirectly connect the housing modules 204a, 204b, 204c, 204d via an intermediate solid source sublimator (not shown). Additionally or alternatively, a reactor gas panel (not shown) on the vapor deposition reactor 202 may direct a flow of gas from the interconnect line 240 to the one or more housing modules 204a, 204b, 204c, 204d. Thus, the bulk fill vessels 208, 212 can feed a plurality of housing modules 204a, 204b, 204c, 204d with the vaporized chemical reactant received from the housing 252 from a distance via the interconnect line 240. As shown, each of the housing modules 204a, 204b, 204c, 204d can include one or more vapor deposition reactors 206a, 206b. Although the interconnect line 240 is shown connecting only one of the housing modules 204a, 204b, 204c, 204d, any combination of the housing modules 204a, 204b, 204c, 204d may receive vaporized reactant via the reactor gas panel.

The remote solid source reactant delivery system 200 can include one or more features of the remote solid source reactant delivery system 100 described above. However, the details are not repeated here, in order to avoid unnecessary replication. For example, the bulk fill vessels 208, 212 may include one or more features of the bulk fill vessels 108, 112 described above.

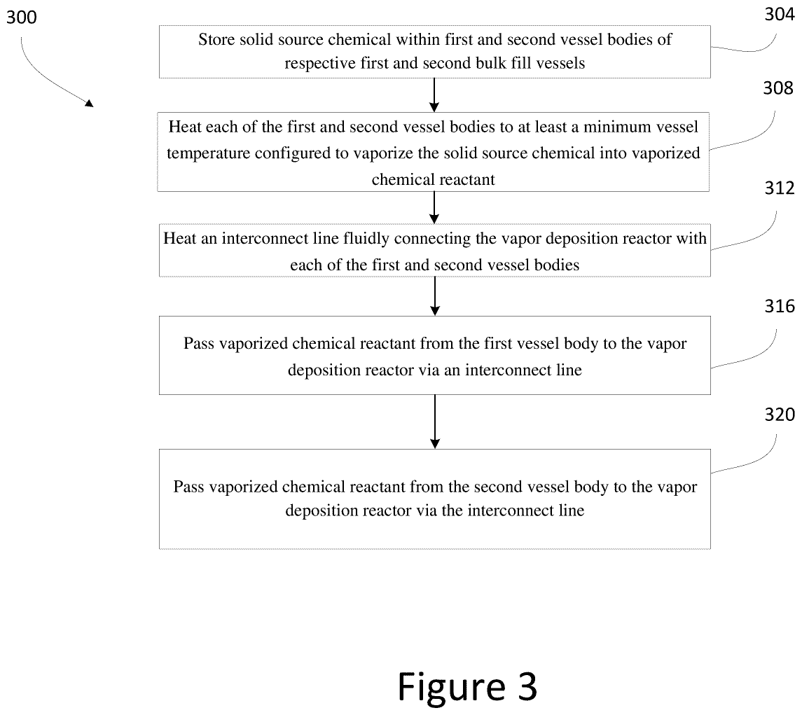

FIG. 3 shows an example method 300 for delivering vaporized chemical reactant to a vapor deposition reactor (e.g., vapor deposition reactor 102, vapor deposition reactor 202), according to some configurations. At block 304, the method 300 includes storing solid source chemical reactant within first and second vessel bodies (e.g., vessel bodies 116, 120) of respective first and second bulk fill vessels (e.g., bulk fill vessels 108, 112, bulk fill vessels 208, 212). At block 308, the method 300 includes heating each of the first and second vessel bodies to at least a minimum vessel temperature. The minimum vessel temperature is configured to vaporize the solid source chemical reactant into vaporized chemical reactant within the bulk fill vessels. As noted above, the minimum vessel temperature may be based at least in part on the solid source chemical and on a pressure within the bulk fill vessels. At block 312, an interconnect line (e.g., interconnect line 140, interconnect line 240) may be heated. The interconnect line can fluidly connect the vapor deposition reactor with each of the first and second vessel bodies. At block 316, the method 300 can include passing vaporized chemical reactant from the first vessel body to the vapor deposition reactor via the interconnect line. In some embodiments, the method 300 includes switching a valve from a first orientation to a second orientation. This switching can change a source of the flow of vaporized chemical reactant. For example, in the first orientation, the first vessel body may be in fluid communication with the vapor deposition reactor, and in the second orientation, the second vessel body may be in fluid communication with the vapor deposition reactor. Each of the bulk fill vessels may be heated to at least a minimum vessel temperature in order to vaporize the chemical reactant. Thus, the vessels can be configured to perform a hot swap described above. A vessel controller (e.g., the vessel controller 164) can be configured to effect the switching and/or to keep a continuous flow of reactant passing to the vapor deposition reactor. At block 320, the vaporized chemical reactant may be passed from the second vessel body to the vapor deposition reactor via the interconnect line. This switchability and/or use of the two bulk fill vessels may allow for reduced interruption of flow of the vaporized chemical reactant from one vessel to the vapor deposition reactor, thus improving substrate deposition and/or improving throughput.

### Illustrative Examples

Below is a set of nonlimiting examples of embodiments described above.

In a 1st example, a remote solid source reactant delivery system for a vapor deposition reactor comprises: a first bulk fill vessel remote from the vapor deposition reactor and configured to hold a first solid source chemical reactant therein, wherein the first bulk fill vessel comprises a first fluid outlet configured to pass a first vaporized chemical reactant out of the first vessel body; a second bulk fill vessel remote from the vapor deposition reactor and configured to hold a second solid source chemical reactant therein, wherein the second bulk fill vessel comprises a second fluid outlet configured to pass a second vaporized chemical reactant out of the second vessel body; and an interconnect line fluidly connecting the vapor deposition reactor with each of the first and second bulk fill vessels, wherein the vapor deposition reactor is separated from both of the first and second bulk fill vessels by at least a minimum distance; a line heater configured to heat at least a portion of the interconnect line to at least a minimum line temperature; and a gas panel comprising a valve, the gas panel disposed between the interconnect line and each of the first and second bulk fill vessels, the valve configured to selectively flow the first vaporized chemical reactant from the first fluid outlet and the second vaporized chemical reactant from the second fluid outlet through the interconnect line.

In a 2nd example, the delivery system of example 1, wherein the valve is configured to continuously flow and/or pulse flow at least one of the first vaporized chemical reactant or the second vaporized chemical reactant through the interconnect line to the vapor deposition reactor.

In a 3rd example, the delivery system of example 2, wherein the minimum line temperature is between about 140° C. and about 190° C.

In a 4th example, the delivery system of any of examples 1-3, wherein the line heater comprises a heating jacket configured to at least partially surround the portion of the interconnect line.

In a 5th example, the delivery system of any of examples 1-4, wherein each of the first and second bulk fill vessels comprises a corresponding vessel heater configured to heat an interior of the respective first and second bulk fill vessel to at least a minimum vessel temperature.

In a 6th example, the delivery system of example 5, wherein the minimum vessel temperature is between about 105° C. and about 155° C.

In a 7th example, the delivery system of any of examples 1-6, wherein the interconnect line fluidly connects the vapor deposition reactor with each of the first and second bulk fill vessels.

In an 8th example, the delivery system of any of examples 1-7, further comprising a housing containing the first and second bulk fill vessels.

In a 9th example, the delivery system of any of examples 1-8, wherein each of the first and second bulk fill vessels is configured to hold at least 15 kg of the first and second solid source chemical reactants, respectively.

In a 10th example, the delivery system of any of examples 1-9, further comprising a flow controller in fluid communication with the interconnect line, the flow controller configured to modify a flux of vaporized chemical reactant through the interconnect line.

In an 11th example, the delivery system of any of examples 1-10, further comprising a vessel controller configured to: receive a signal indicating that a volume of solid source chemical reactant within the first bulk fill vessel is below a minimum threshold amount; and instruct the valve to stop the flow of the first vaporized chemical reactant through the interconnect line and start the flow of the second chemical reactant through the interconnect line.

In a 12th example, the delivery system of any of examples 1-11, wherein each of the first and second fluid outlets comprises a corresponding valve configured to control a flow of gas therethrough.

In a 13th example, the delivery system of any of examples 1-12, wherein the minimum distance is about 15 m.

In a 14th example, a delivery system comprising: a plurality of bulk fill vessels each comprising: a vessel body configured to hold a first solid source chemical reactant therein; a lid comprising a first fluid outlet configured to pass a first vaporized chemical reactant out of the first vessel body; and a vessel heater configured to heat an interior of the vessel body to at least a vessel temperature of between about 105° C. and about 155° C.; an interconnect line fluidly connecting a vapor deposition reactor with each of the bulk fill vessels, wherein the vapor deposition reactor is separated from each of the bulk fill vessels by at least a minimum distance of at least 5 m; and a line heater configured to heat at least a portion of the interconnect line to at least a line temperature of between, for example, about 140° C. and about 190° C.

In a 15th example, the delivery system of example 14, further comprising a second bulk fill vessel comprising: a second vessel body configured to hold a second solid source chemical reactant therein; and a second lid comprising a second fluid outlet configured to pass a second vaporized chemical reactant out of the second vessel body.

In a 16th example, the delivery system of either of examples 14 and 15, further comprising a second bulk fill vessel comprising a valve disposed between the interconnect line and each of the first and second bulk fill vessels, the valve configured to selectively flow the first vaporized chemical reactant and the second vaporized chemical reactant through the interconnect line.

In a 17th example, a method for delivering vaporized chemical reactant to a vapor deposition reactor, the method comprising: storing solid source chemical reactant within first and second vessel bodies of respective first and second bulk fill vessels; heating each of the first and second vessel bodies to at least a minimum vessel temperature at which the solid source chemical reactant is vaporized; heating an interconnect line fluidly to at least a minimum line temperature, the interconnect line connecting the vapor deposition reactor with each of the first and second vessel bodies; passing vaporized chemical reactant from the first vessel body to the vapor deposition reactor via the interconnect line; and passing vaporized chemical reactant from the second vessel body to the vapor deposition reactor via the interconnect line.

In an 18th example, the method of example 17, further comprising: switching a valve from a first orientation to a second orientation, wherein, in the first orientation, the first vessel body is in fluid communication with the vapor deposition reactor, and wherein, in the second orientation, the second vessel body is in fluid communication with the vapor deposition reactor.

In a 19th example, the method of either of examples 17 and 18, wherein the minimum vessel temperature is between about 105° C. and about 155° C.

In a 20th example, the method of any of examples 17-19, wherein the minimum line temperature is between about 140° C. and about 190° C.

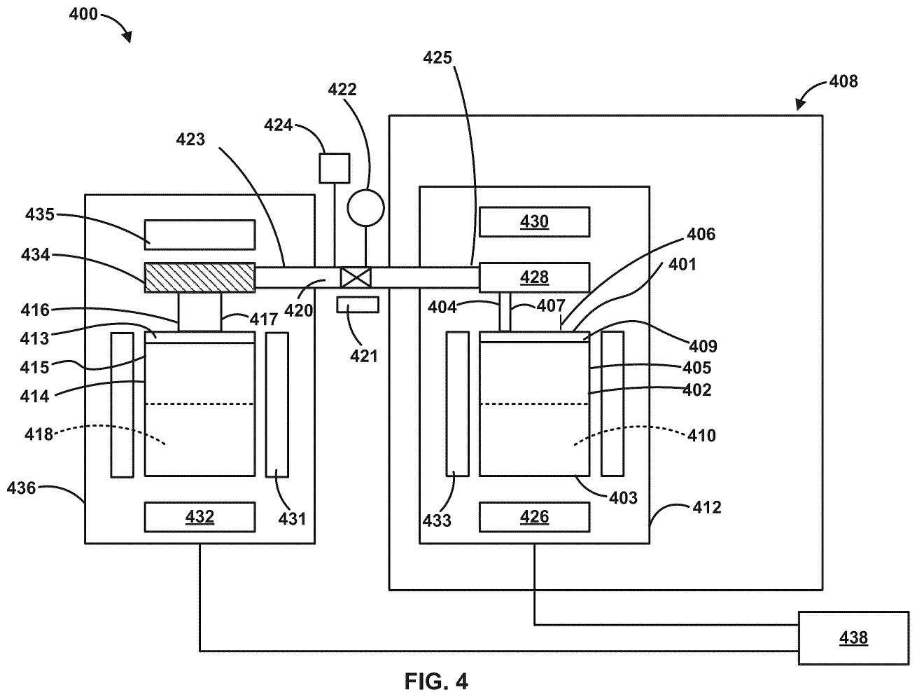

Turning again to the figures, FIG. 4 illustrates reactant delivery system 400 in accordance with additional examples of the disclosure. In the illustrated example, the reactant delivery system 400 includes a first vessel 402 forming part of a reactor system 408, a first housing 412 enclosing the first vessel 402, a second vessel 414 exterior the first housing 412 and remote from the reactor system 408, a conduit 420 fluidly coupled to the first vessel 402 and the second vessel 414, and a flow control device 422. As set forth in more detail below, the second vessel 414 can be used to refill the first vessel 402. As reactant (e.g., solid source chemical reactant 410) is depleted from the first vessel 402, the reactant can be replenished from reactant (e.g., solid source chemical reactant 418) within the second vessel 414. As or once reactant within the second vessel becomes depleted, the second vessel 414 can be replaced or refilled with relatively little disruption to operation of the reactor system 408.

The first vessel 402 is configured to retain a solid source reactant. The first vessel 402 includes a first vessel lid 409, a first vessel body 405, a first vessel inlet 404 and a first vessel outlet 406. The first vessel 402 can also include an inert gas inlet 407 to receive a carrier gas as described herein. A configuration of the first vessel 402 can be similar to the configuration of the bulk fill vessels 108, 112 described above. However, in some cases, because the first vessel 402 forms part of the reactor system 408 or is on board, the first vessel 402 may have a smaller configuration and/or a smaller footprint, compared to a footprint of the bulk fill vessels 108, 112. For example, a ratio of the height of the first vessel 402 to the width/diameter thereof can be greater than about 0.5, greater than about 0.75, greater than about 0.95, greater than about 1, greater than about 1.25, greater than about 1.5, greater than about 2, greater than any value therebetween, or fall within any range having endpoints therein. For example, in some embodiments, the ratio of height to width is about 0.95 or about 1.25. In some embodiments, a height of the first vessel 402 is about 15 cm or about 25 cm and a width is about 15 cm or about 25 cm. The first vessel 402 can be configured to contain about 20 to about 30 kg of reactant. The reactant can be any suitable solid source reactant, such as molybdenum or tungsten halides or oxyhalides.

The first vessel 402 can be within the first housing 412. The first housing can be the same or similar to housing 152 described above. A pressure within the first housing can be below ambient pressure. For example, a pressure within the first housing 412 can be as noted above in connection with the housing 152 or can be between about 10 Torr and about 20 Torr or between about 1 Torr and below atmospheric pressure.

The second vessel 414 is configured to retain the solid source chemical reactant 418. The second vessel 414 can be similar to the bulk refill vessels 108, 112 described above. For example, the second vessel can include a second vessel lid 413, a second vessel body 415, and a second vessel outlet 416. The second vessel can also include a second vessel inlet 417 configured to receive an inert or inactive gas as described herein. The second vessel 414 can be configured with dimensions and capacity as described above in connection with the bulk refill vessels 108, 112. By way of example, the second vessel 414 can be configured to retain about 20 kg to about 80 kg or about 50 kg of reactant of the solid source chemical reactant 418.

As illustrated, the second vessel 414 can be retained within a second housing 436 that encloses the second vessel 414. In accordance with examples of the disclosure, a pressure within the second housing 436 is greater than a pressure within the first housing 412. For example, a pressure within the second housing can be between about 1 Torr and below atmospheric pressure or between about 1 Torr and about 750 Torr. In some cases, a pressure within the second housing can be about atmospheric ambient pressure or be between about 1 and about 100 Torr below atmospheric or ambient pressure. The second housing 436 can be at a fab level, next to the reactor system 408, or remote from the reactor system 408 as described above in connection with the remote solid source reactant delivery system 100. For example, the second housing 436 and/or the second vessel 414 can be a minimum distance (as described above) from the reactor system 408 and/or the first vessel 402. A pressure within the second vessel can be, for example, about 2 Torr to about 10 Torr.

A vessel heater 432 can be used to heat the second vessel 414. The vessel heater 432 can be the same or similar to the vessel heater 132 described above. Additional heater(s) 435 can be used to heat the second vessel lid 413 and/or a valve plate 434. The vessel heater 432 and/or the additional heaters(s) 435 can be the same or similar to the vessel heaters 132, 136 and other heaters described above.

The valve plate 434 can be used to control flow of reactant from the second vessel 414 to the first vessel 402. The valve plate 434 can include one or more valves, fluidly coupled to the second vessel inlet 417, for controlling a flow of a carrier gas to an interior of the second vessel 414 and/or the vaporized reactant to the first vessel 402. The valve plate 434 can be located within the second housing 436. As illustrated, the valve plate 434 can be disposed between the second vessel outlet 416 and the first vessel inlet 404. The valve plate 434 can be heated as described above in connection with system 100. For example, the valve plate 434 can be heated to a temperature above the sublimation or condensation temperature of the reactant. By way of particular example, when the reactant is molybdenum chloride, the valve plate 434 can be heated to a temperature of about 150° C.

The conduit 420 fluidly couples the second vessel outlet 416 and the first vessel inlet 404. The conduit can be the same or similar to interconnect line 140 described above. Further, the conduit 420 can be heated using a line heater 421, which can be the same or similar to the line heater 144 described above. The line heater 421, in connection with a controller 438, described below, can be configured to heat the conduit 420 to a temperature greater than a temperature of the second vessel 414. For example, the temperature of the conduit 420 can be greater than 10° C., 15° C., 20° C., 30° C., or 50° C. greater than a temperature of the second vessel 414. In accordance with examples of the disclosure, the conduit 420 can be heated, such that a temperature gradient forms between a first end 423 of the conduit coupled to the second vessel 414 and a second end 425 coupled to the first vessel 402. The temperature gradient can be 5° C., 10° C., 15° C., 20° C., 30° C., or 50° C., or any temperature therebetween.

The flow control device 422 can include any suitable flow control device, such as a flow control device/flow controller 160 described above. As illustrated, the flow control device 422 can be within the conduit 420 to control and/or meter an amount of transfer of a vapor of the solid source chemical reactant 418 from the second vessel 414 to the first vessel 402. By way of example, the flow control device 422 can be or include one or more of a mass flow controller and a mass flow meter.

The reactant delivery system 400 can further include a valve plate 428, which can be the same or similar to the gas panel 148 described above. The valve plate 428 can include one or more valves, fluidly coupled to the first vessel outlet 406, for controlling a flow of vapor therethrough and/or between the second vessel 414 and the first vessel 402 and/or between the first vessel 402 and a vapor deposition reactor, which can be the same or similar to the vapor deposition reactor 102. Additionally or alternatively, the valve plate 428 can include a valve to control a flow of a carrier gas through the first vessel inlet 404 and/or inlet 407. The valve plate 428 can be located within the first housing 412. As illustrated, the valve plate 428 can be disposed between the first vessel inlet 404 and the vapor deposition reactor. Additionally or alternatively, the vapor deposition reactor can include a reactor gas panel, such as reactor gas panel 172, that includes one or more corresponding valves configured to control a flow of gas into a vapor deposition reaction chamber. As described above, the reactor gas panel can direct a flow of vaporized reactant to one or more vapor deposition reaction chambers of the vapor deposition reactor.

One or more heaters 430 can be used to heat the valve plate 428. The one or more heaters 430 can be the same or similar to heaters described above. For example, the one or more heaters 430 can be or include radiant heaters that can maintain a thermal gradient from a top 401 of the first vessel to a bottom 403 of the first vessel. Additionally or alternatively, the one or more heaters 430 can be configured to heat the valve plate to a temperature greater than the sublimation or condensation temperature of the reactant. In accordance with examples of the disclosure, the one or more heaters 430 heat the valve plate 428 to a temperature greater than the heaters 435 heat the valve plate 434 and/or of a temperature of the first vessel 402. By way of examples, the one or more heaters 435 can heat the valve plate 434 to a temperature greater than 10° C., 15° C., 20° C., 30° C., or 50° C. greater than a temperature of the first valve plate 434 and/or of the first vessel 402.

The reactant delivery system 400 can also include one or more heaters 433, such as heater jackets, to heat a sidewall of the first vessel 402. Additionally or alternatively, the reactant delivery system 400 can include one or more heaters 431, such as heater jackets, to heat a sidewall of the second vessel 414.

As illustrated, the reactant delivery system 400 can further include a vessel cooling device 426 to actively or passively cool a bottom of the first vessel 402. Cooling the bottom of the first vessel 402 can facilitate filling the first vessel 402 from the bottom up. For example, the cooling device 426 can cool a temperature of the bottom of the first vessel 402 to a temperature less than 10° C., 15° C., 20° C., 30° C., or 50° C. or even less than a temperature of a top of the first vessel 402. In accordance with examples of the disclosure, the cooling device 426 includes a fluid cooled device, a convention cooled device, a thermoelectric device, and/or a heat sink.

The reactant delivery system 400 can further include a pressure transducer 424. The pressure transducer 424 can include any suitable pressure measurement device, such as a heated capacitance manometer, to measure a pressure within the conduit 420. The pressure transducer 424 and/or the flow control device 422 can be used to measure an amount of reactant transferred from the second vessel 414 to the first vessel 402.

The reactant delivery system 400 can further include a controller 438 to control various devices and functions of the reactant delivery system 400 and/or the reactor system 408. The controller 438 can be configured with closed-loop control to control an amount and/or transfer rate of material transferred from the second vessel 414 into the first vessel 402. An amount of reactant consumed or the amount to be replenished can be measured anywhere downstream of the second vessel 414. For example, the controller can receive an input of an amount of the reactant delivered to an accumulator or to the reaction chamber as an input for the closed-loop control.

The controller 438 can be configured to independently control a temperature of the first vessel 402 and a temperature of the second vessel 414. In some cases, the controller 438 can be further configured to regulate a temperature of the bottom 403 of the first vessel to be lower than a temperature of the top 401 of the first vessel—e.g., to facilitate filling the first vessel 402 from the second vessel 414. In some cases, the controller 438 is configured to automatically heat the second vessel 414, when an amount of reactant in the first vessel 402 is below a threshold amount and/or to cease flow of reactant from the second vessel 414 to the first vessel 402 when a threshold amount of the reactant is within the first vessel i.e., when the first vessel 402 is filled to a desired level. Additionally or alternatively, the controller 438 can be configured to change a temperature gradient between the top 401 and the bottom 403 of the first vessel (e.g., by controlling the one or more heaters 430 and/or the cooling device 426) to maintain a desired temperature gradient (e.g., greater than 5° C., 10° C., 15° C., 20° C., 30° C., or 50° C.) from the top 401 to the bottom 403 of the first vessel 402, particularly during a fill process.

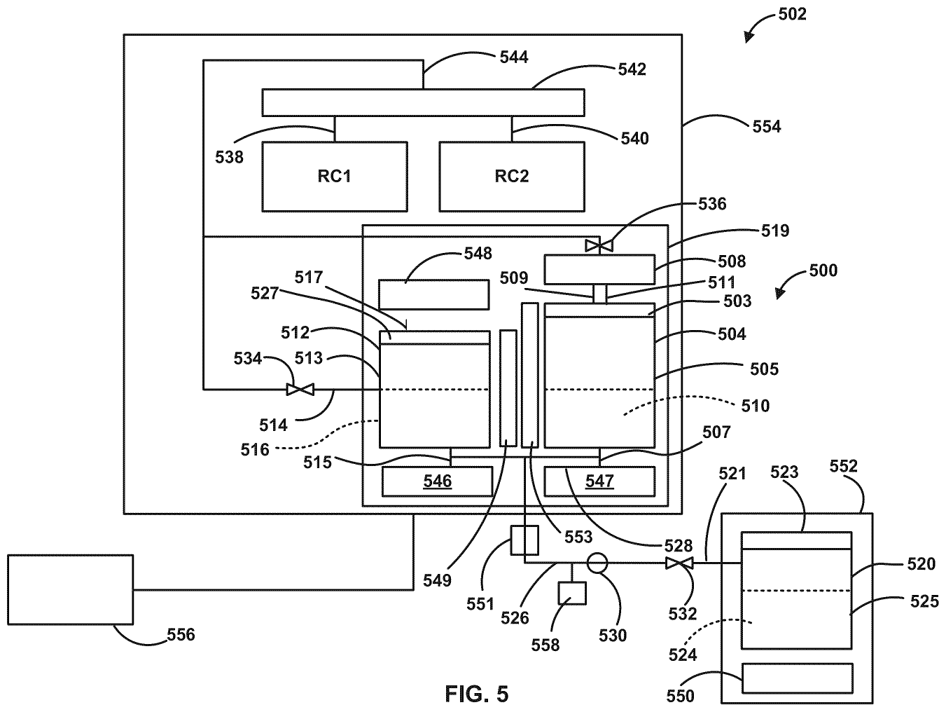

FIG. 5 illustrates another reactant delivery system 500 suitable for use with a reactor system 502 in accordance with further examples of the disclosure. In this case, the delivery system 500 includes a first vessel 504, a second vessel 512, a third vessel 520, a conduit 526 fluidly coupling the third vessel to the second vessel 512 and/or to the first vessel 504, and a flow control device 530 within the conduit 526 to control an amount of transfer of a vapor of a solid source reactant 524 from the third vessel 520 to one or more of the first vessel 504 or the second vessel 512. In this case, the first vessel 504 can be a primary delivery vessel, the second vessel 512 can be a support vessel, and the third vessel 520 can be a remote fill vessel. The delivery system 500 can be used to reduce downtime associated with filling reactant vessels and can allow for continuous running of reactor systems or modules, without stopping running to refill a reactant vessel.

The first vessel 504 can be the same as first vessel 402 described above in connection with FIG. 4. The first vessel 504 can include a first vessel lid 503 and a first vessel body 505. As illustrated, the first vessel 504 can form part of the reactor system 502. As above, the first vessel is configured to contain a reactant 510. The first vessel includes a first vessel inlet 507, a first vessel outlet 509, and can include a carrier gas inlet 511. The first vessel inlet 507 can be coupled to an outlet 521 of the third vessel 520. As illustrated, the first vessel outlet 509 is fluidly coupled to one or more reaction chambers RC1, RC2.

The second vessel 512 can also be the same or similar to the first vessel 402. In some cases, the second vessel 512 can have a smaller capacity (e.g., about 50 v %, 60 v %, 75 v %, 80 v %, or any range in between) than a volume of the first vessel 504.

The second vessel 512 includes a second vessel lid 527, a second vessel body 513, a second vessel outlet 514, and a second vessel inlet 515. The second vessel 512 is configured to retain the solid source reactant 516. The second vessel inlet 515 can be coupled to the third vessel outlet 521. The second vessel 512 can include a second inlet 517 coupled to a carrier gas. The second vessel outlet 514 is fluidly coupled to the one or more reaction chambers RC1, RC2.

The first vessel 504 and the second vessel 512 can be within a first housing 519. The first housing 519 can be controlled to a desired pressure, such as a pressure noted above in connection with the first housing 412.

The third vessel 520 can be the same or similar to the second vessel 414 described above. The third vessel 520 is suitably remote from the reactor system 502 and can be configured to retain the solid source reactant 524. The third vessel 520 can include a third vessel lid 523 and a third vessel body 525, which can be the same or similar to vessel bodies and lids described above. The third vessel 520 can be contained within a second housing 552, which can be the same or similar as the second housing 436 described above. The second housing 552 can have an interior pressure as described above in connection with the second housing 436.

The reactant delivery system 500 can include heaters 508, 548, and 550, heater jackets 549, 553, line heater 551, and/or cooling device 546, 548, which can be the same or similar to the heaters and cooling devices described above in connection with FIG. 4. Further, the reactant delivery system 500 can include one or more valve plates as described above.

The conduit 526 can be the same or similar to the conduit 420. As noted above, the conduit 526 fluidly couples the third vessel outlet 521 to the first vessel inlet 507 and/or to the second vessel inlet 515. The reactant delivery system 500 can also include a line heater, such as the heater 551, to maintain the conduit at a desired temperature or desired gradient, as noted above.

The flow control device 530 can be located within the conduit 526. The flow control device 530 can be configured to work with a controller 556 to control an amount of transfer of a vapor of the solid source reactant from the third vessel 520 to one or more of the first vessel 504 or the second vessel 512.

The reactant delivery system 500 can also include a pressure transducer 558. The pressure transducer 558 can include any suitable pressure measurement device, such as a device noted above in connection with the pressure transducer 424. The pressure transducer 558 and/or the flow control device 530 can be used to measure an amount of reactant transferred from the third vessel 520 to the first vessel 504 and/or the second vessel 512.

The reactant delivery system 500 can also include an isolation valve 532. The isolation valve 532 can be used when switching third vessel 520 for a new vessel.

The reactor system 502 can also include a reactor gas panel 542, which can direct a flow of vaporized reactant to one or more vapor deposition reaction chambers RC1, RC2 of the vapor deposition reactor system 502. RC1 and RC2 can have respective inlets 538, 540. The reactor gas panel 542 can be fluidly coupled to the first vessel 504 and the second vessel 512 via a line 544 and valves 534, 536.

The reactor gas panel 542 can be the same or similar to the reactor gas panel 172 described above. Reaction chambers RC1 and RC2 can form part of a process module 554. The reactor system 502 can include 1, 2, 3, 4, or more process modules, wherein each of the process modules is fluidly coupled to the third vessel 520.

The controller 556 can be similar to the controller 438 described above. Generally, the controller 556 can be configured to independently control a temperature of the first vessel 504, a temperature of the second vessel 512, and a temperature of the third vessel 520 to provide desired flow of the reactant from the third vessel 520 to the first vessel 504 and/or the second vessel 512. For example, the controller 556 can be configured to automatically increase a temperature of the second vessel 512 and/or the third vessel 520 when an amount of the reactant 510 in the first vessel 504 is below a threshold amount. Additionally or alternatively, the controller 556 can be configured to automatically increase a temperature of the third vessel 520 when an amount of reactant 516 in the second vessel 512 is below a threshold amount.

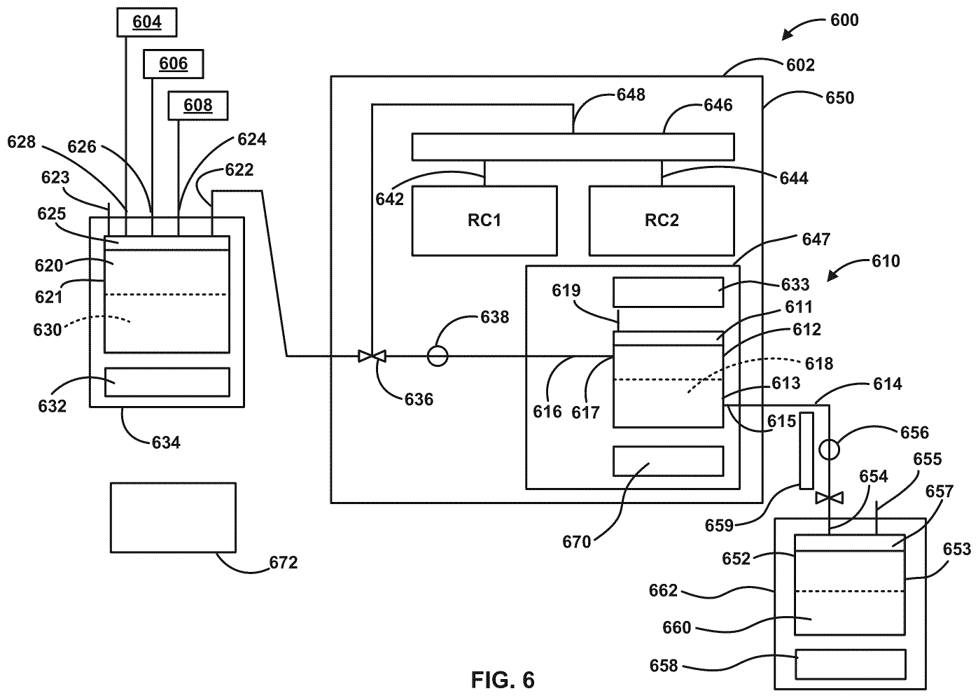

FIG. 6 illustrates a reactor system 600 in accordance with yet additional embodiments of the disclosure. The reactor system 600 includes one or more process modules 602, 604, 606, 608, and a reactant delivery system 610.

The process modules 602-608 can include any suitable process module, such as a process module described herein. The exemplary process modules 602-608, as illustrated in connection with process module 602, can include a first reaction chamber RC1, a second reaction chamber RC2, a reactor gas panel 646, and a first vessel 612. The reaction chambers RC1 and RC2, the reactor gas panel 646, and the first vessel 612 can be as described above in connection with, for example, FIG. 5.

The reactant delivery system 610 includes the first vessel 612, a second vessel 620, a third vessel 652, and a flow control device 656. In accordance with examples of the disclosure, each process module 602-608 includes a first vessel. The second vessel 620 and/or the third vessel 652 can be fluidly coupled to one, two, three, four or more process modules.

The first vessel 612 is configured to contain a solid source reactant 618. The first vessel 612 can include a first vessel lid 611 and a first vessel body 613. The first vessel 612 includes a first vessel inlet 615, a first vessel outlet 617, and another first vessel inlet 619, which can be the same or similar to first vessel inlets and outlets described above. For example, the first vessel inlet 615 can receive reactant from the third vessel 652. The first vessel inlet 619 can receive a carrier gas. The first vessel outlet 617 provides the vaporized reactant to line 616 to deliver the reactant to the reactor gas panel 646 and eventually to one or more reaction chambers RC1, RC2. The first vessel 612 can be contained within a first housing 647, which can be the same or similar to first housing 519 described above in connection with FIG. 5.

The second vessel 620 can be configured to contain the reactant 630 and can be the same or similar to the second vessel 414, described above in connection with FIG. 4. As illustrated, the second vessel 620 can be remote from the reactor system 600 and/or one or more of the process modules 602-608 (e.g., by a minimum distance).

The second vessel 620 includes a second vessel lid 625, a second vessel body 621, and a second vessel outlet 622. The second vessel 620 can also include another inlet 623 to receive a carrier gas as described above. The second vessel outlet 622 or multiple second vessel outlets (e.g., outlets 624-628) can be fluidly coupled to each of the one or more process modules. The second vessel 620 can be contained within a second housing 634, which can be the same or similar to the second housing 436, described above. The pressure within the second housing 634 can be as described above in connection with the second housing 436.

The third vessel 652 can be the same or similar to the third vessel 520 described above in connection with FIG. 5. The third vessel 652 can include a third vessel lid 6517, a third vessel body 653, a third vessel outlet 654, and can include a third vessel inlet 655 to receive a carrier gas. As illustrated, the third vessel 652 can be configured to retain the solid source reactant 660. The third vessel 652 can be remote from the reactor system 600 e.g., by a minimum distance as described herein. The third vessel 652 can be contained within a third housing 662, which can be the same or similar to the housing 552 discussed above.

The conduit 614 fluidly couples the third vessel outlet 654 to the first vessel inlet 615.

The flow control device 656 can be within the conduit 614 to control an amount of transfer of a vapor of the solid source reactant from the third vessel 652 to one or more of the process modules 602-608.

The reactor gas panel 646 and the reaction chambers RC1, RC2 can be as described above. Similarly, heaters 632, 633, 658, 659 and cooling device 670 can be the same or similar to the heaters and cooling device described above.

The reactor system 600 can also include a controller 672. The controller 672 can be configured to independently control a temperature of the first vessel 612, a temperature of the second vessel 620, and a temperature of the third vessel 652, as described above. In particular, the controller 672 can be configured to control a temperature of the first vessel 612 with a temperature gradient as described above. Additionally or alternatively, the controller 672 can be configured to automatically heat or cool a vessel to provide desired reactant transfer as described herein. For example, the controller 672 can be configured to automatically increase a temperature of the third vessel 652 when an amount of reactant in the first vessel 612 is below a threshold amount to, for example, fill the first vessel as described above. Additionally or alternatively, the controller 672 can be configured to automatically increase a temperature of the second vessel 620 when an amount of reactant in the first vessel 612 is below a threshold amount to, for example, continue to provide the reactant to the one or more process modules 602-608 while, for example, the first vessel is filled.

### Other Considerations

In the foregoing specification, the invention has been described with reference to specific embodiments thereof. It will, however, be evident that various modifications and changes may be made thereto without departing from the broader spirit and scope of the invention. The specification and drawings are, accordingly, to be regarded in an illustrative rather than restrictive sense.

Indeed, it will be appreciated that the systems and methods of the disclosure each have several innovative aspects, no single one of which is solely responsible or required for the desirable attributes disclosed herein. The various features and processes described herein may be used independently of one another, or may be combined in various ways. All possible combinations and subcombinations are intended to fall within the scope of this disclosure.

Certain features that are described in this specification in the context of separate embodiments also may be implemented in combination with a single embodiment. Conversely, various features that are described in the context of a single embodiment also may be implemented in multiple embodiments separately or in any suitable subcombination. Moreover, although features may be described herein as acting in certain combinations and even initially claimed as such, one or more features from a claimed combination may in some cases be excised from the combination, and the claimed combination may be directed to a subcombination or variation of a subcombination. No single feature or group of features is necessary or indispensable to each and every embodiment.

It will be appreciated that conditional language used herein, such as, among others, “can,” “could,” “might,” “may,” “e.g.,” and the like, unless specifically stated otherwise, or otherwise understood within the context as used, is generally intended to convey that certain embodiments include, while other embodiments do not include, certain features, elements and/or steps. Thus, such conditional language is not generally intended to imply that features, elements and/or steps are in any way required for one or more embodiments or that one or more embodiments necessarily include logic for deciding, with or without author input or prompting, whether these features, elements and/or steps are included or are to be performed in any particular embodiment. The terms “comprising,” “including,” “having,” and the like are synonymous and are used inclusively, in an open-ended fashion, and do not exclude additional elements, features, acts, operations, and so forth. Also, the term “or” is used in its inclusive sense (and not in its exclusive sense) so that when used, for example, to connect a list of elements, the term “or” means one, some, or all of the elements in the list. In addition, the articles “a,” “an,” and “the” as used in this application and the appended claims are to be construed to mean “one or more” or “at least one” unless specified otherwise. Similarly, while operations may be depicted in the drawings in a particular order, it is to be recognized that such operations need not be performed in the particular order shown or in sequential order, or that all illustrated operations be performed, to achieve desirable results. Further, the drawings may schematically depict one more example processes in the form of a flowchart. However, other operations that are not depicted may be incorporated in the example methods and processes that are schematically illustrated. For example, one or more additional operations may be performed before, after, simultaneously, or between any of the illustrated operations. Additionally, the operations may be rearranged or reordered in other embodiments. In certain circumstances, multitasking and parallel processing may be advantageous. Moreover, the separation of various system components in the embodiments described herein should not be understood as requiring such separation in all embodiments, and it should be understood that the described components and systems may generally be integrated together in a single product or packaged into multiple products. Additionally, other embodiments are within the scope of the following claims. In some cases, the actions recited in the claims may be performed in a different order and still achieve desirable results.

Accordingly, the claims are not intended to be limited to the embodiments shown herein, but are to be accorded the widest scope consistent with this disclosure, the principles and the features disclosed herein. For example, although many examples within this disclosure are provided with respect to supplying vapor from solid sources for feeding deposition chambers for semiconductor fabrication, certain embodiments described herein may be implemented for a wide variety of other applications and/or in numerous other contexts.

What is claimed is:

1. A reactant delivery system comprising:
a first vessel comprising a first vessel inlet and a first vessel outlet, the first vessel forming part of a reactor system and configured to retain a solid source reactant;
a first housing enclosing the first vessel;
a second vessel comprising a second vessel outlet, the second vessel exterior the first housing and remote from the reactor system, the second vessel configured to retain the solid source reactant;
a conduit fluidly coupled to the second vessel outlet and the first vessel inlet; and
a flow control device within the conduit to control an amount of transfer of a vapor of the solid source reactant from the second vessel to the first vessel,
wherein a pressure within the first housing is less than an ambient pressure exterior the first housing.

2. The reactant delivery system of claim 1, further comprising a valve plate within the first housing, the valve plate comprising one or more valves fluidly coupled to the first vessel outlet.

3. The reactant delivery system of claim 1, further comprising a pressure transducer to measure a pressure within the conduit.

4. The reactant delivery system of claim 1, wherein the flow control device comprises one or more of a mass flow controller and a mass flow meter.

5. The reactant delivery system of claim 1, wherein the pressure within the first housing is between about 1 Torr and below atmospheric pressure or between about 10 Torr and about 20 Torr.

6. The reactant delivery system of claim 1, comprising a second housing enclosing the second vessel, wherein a pressure within the second housing is greater than the pressure within the first housing.

7. The reactant delivery system of claim 1, further comprising a controller to control a temperature of the first vessel and a temperature of the second vessel.

8. The reactant delivery system of claim 7, wherein the controller is configured to regulate a temperature of a bottom portion of the first vessel to be lower than a temperature of a top portion of the first vessel.

9. The reactant delivery system of claim 7, wherein the controller is configured to automatically heat the second vessel, when an amount of reactant in the first vessel is below a threshold amount.

10. A reactant delivery system comprising:
a first vessel comprising a first vessel inlet and a first vessel outlet, the first vessel forming part of a reactor system and configured to retain a solid source reactant;
a second vessel comprising a second vessel outlet and a second vessel inlet, the second vessel configured to retain the solid source reactant;
a third vessel comprising a third vessel outlet, the third vessel remote from the reactor system and configured to retain the solid source reactant;
a conduit fluidly coupling the third vessel outlet to the first vessel inlet and to the second vessel inlet; and
a flow control device within the conduit to control an amount of transfer of a vapor of the solid source reactant from the third vessel to one or more of the first vessel or the second vessel,
wherein the first vessel outlet and the second vessel outlet are fluidly coupled to a reaction chamber.

11. The reactant delivery system of claim 10, further comprising a heater to heat the conduit.

12. The reactant delivery system of claim 10, wherein the first vessel and the second vessel are contained within a first housing.

13. The reactant delivery system of claim 12, wherein the third vessel is contained within a second housing.

14. The reactant delivery system of claim 10, further comprising a controller configured to independently control a temperature of the first vessel, a temperature of the second vessel, and a temperature of the third vessel.

15. The reactant delivery system of claim 14, wherein the controller is configured to automatically increase the temperature of the second vessel when an amount of reactant in the first vessel is below a threshold amount.

16. The reactant delivery system of claim 10, wherein the first vessel is within a first housing, the second vessel is within a second housing, and the third vessel is within a third housing.

17. The reactant delivery system of claim 16 wherein the second vessel is remote from the reactor system.

18. A reactor system comprising:
one or more process modules; and
a reactant delivery system comprising:
a first vessel comprising a first vessel inlet and a first vessel outlet, the first vessel forming part of the reactor system and configured to retain a solid source reactant;
a second vessel comprising a second vessel outlet, the second vessel configured to retain the solid source reactant;
a third vessel comprising a third vessel outlet, the third vessel remote from the reactor system and configured to retain the solid source reactant;
a conduit fluidly coupling the third vessel outlet to the first vessel inlet; and
a flow control device within the conduit to control an amount of transfer of a vapor of the solid source reactant from the third vessel to the one or more process modules,
wherein the second vessel outlet is fluidly coupled to each of the one or more process modules.

19. The reactor system of claim 18, further comprising a controller configured to independently control a temperature of the first vessel, a temperature of the second vessel, and a temperature of the third vessel.

20. The reactor system of claim 19, wherein the controller is configured to automatically increase the temperature of the third vessel when an amount of reactant in the first vessel is below a threshold amount.
